(19) United States
(12) Patent Application Publication
(10) Pub. No.: US 2014/0118941 A1
(43) Pub. Date: May 1, 2014

(54) DEVICE WITH FIRE PROTECTION

(71) Applicant: TELLABS OY, Espoo (FI)

(72) Inventors: Antti HOLMA, Espoo (FI); Petri KOHONEN, Vantaa (FI); Jari-Pekka LAIHONEN, Espoo (FI); Pasi RAIKKONEN, Roykka (FI); Juha AHVENAINEN, Espoo (FI)

(73) Assignee: TELLABS OY, Espoo (FI)

(21) Appl. No.: 14/068,069

(22) Filed: Oct. 31, 2013

(30) Foreign Application Priority Data
Oct. 31, 2012 (FI) 20126141

(51) Int. Cl. A62C 2/06; H05K 7/20; A62C 3/16

(52) U.S. Cl. CPC A62C 3/14; A62C 3/16; H05K 7/20136
USPC 361/695; 454/369

(57) ABSTRACT

A device provided with fire protection includes a casing (102), electrical components (103) inside the casing, and a fan element (104). The casing includes a first wall having ventilation apertures and the fan element is configured to produce ventilation flow through the ventilation apertures so as to cool the electrical components. The device further includes a fire protection element (105) including thermally expanding material (109) configured to suppress the ventilation flow via the ventilation apertures in response to a situation in which the thermally expanding material is exposed to heat and gets expanded. The fire protection element is outside the casing, the fan element is mechanically supported to the casing, and the fire protection element is removable and re-installable without detaching the mechanical support between the casing and the fan element. Therefore, the fire protection element can be a post-installable element.

### FIELD OF THE INVENTION

The invention relates to a device comprising a fire-protection element for suppressing ventilation flow when the fire protection element is exposed to heat. Furthermore, the invention relates to equipment comprising one or more component devices provided with fire protection and a body device for receiving the component devices. The equipment can be, for example but not necessarily, telecommunication equipment.

### BACKGROUND

In many cases there is a requirement to provide a device with a fire retardant arrangement so as to limit damages being caused in a case of fire and also to limit spread of the fire. The device can be, for example but not necessarily, a telecommunication device such as an internet protocol “IP” router, an Ethernet switch, an Asynchronous Transfer Mode “ATM” switch, and/or a MultiProtocol Label Switching “MPLS” switch. The device comprises typically a casing provided with ventilation apertures, electrical components inside the casing, and at least one fan element configured to produce ventilation flow through the ventilation apertures so as to cool the electrical components. In order to limit spread of possible fire, the device can be provided with a fire protection element that comprises thermally expanding material and is positioned so that the thermally expanding material suppresses the ventilation flow via the ventilation apertures in response to a situation in which the thermally expanding material is exposed to heat and, as a corollary, gets expanded.

For example, in conjunction with telecommunication devices, the above-mentioned fire protection element is required in some market areas whereas the fire protection element is not required in some other market areas. On the other hand, the fire protection element is a quite expensive element and, therefore, providing devises targeted to all market areas with a fire protection element is not an economically viable approach. Therefore, vendors of telecommunication devices may be forced to have two types of devices in their product portfolio: devices with a fire protection element and devices without a fire protection element. As evident, having two types of devices in a product portfolio causes cost and, thus, there is a need to provide technical solutions for eliminating or at least reducing the above-mentioned inconveniences.

### SUMMARY

The following presents a simplified summary in order to provide a basic understanding of some aspects of various invention embodiments. The summary is not an extensive overview of the invention. It is neither intended to identify key or critical elements of the invention nor to delineate the scope of the invention. The following summary merely presents some concepts of the invention in a simplified form as a prelude to a more detailed description of exemplifying embodiments of the invention.

In accordance with the invention, there is provided a new device that can be, for example but not necessarily, a telecommunication device. A device according to the invention comprises:
a casing comprising a first wall having one or more ventilation apertures,
at least one electrical component inside the casing,
at least one fan element configured to produce ventilation flow through the one or more ventilation apertures so as to cool the at least one electrical component, and
a fire protection element comprising thermally expanding material configured to suppress the ventilation flow via the one or more ventilation apertures in response to a situation in which the thermally expanding material is exposed to heat and gets expanded.

The at least one fan element is mechanically supported to the casing and the fire protection element is removable and re-installable without detaching the mechanical support between the casing and the at least one fan element. Therefore, the fire protection element can be a post-installable element and thus the need to have two types of devices in a product portfolio can be avoided. The fire protection element can be installed outside the casing or, alternatively, the fire protection unit can be an element that can be installed in the casing via an aperture of the casing.

In accordance with the invention, there is provided also a new equipment comprising:
at least one component device according to the invention, and
a body device comprising mechanical structures for receiving the component device so that the component device is in its operating position when supported by the mechanical structures.

The mechanical structures of the body-device are suitable for supporting the component device in its operating position also when the component device is without the fire protection element. Therefore, the fire protection element of the component device can be a post-installable element and thus the need to have two types of equipment in a product portfolio can be avoided.

The equipment can be, for example but not necessarily, telecommunication equipment where the body device is a rack for supporting the component device and the component device may comprise a processing system for supporting one or more of the following data transfer protocols: Internet Protocol “IP”, Ethernet protocol, MultiProtocol Label Switching “MPLS” protocol, Asynchronous Transfer Mode “ATM”.

A number of non-limiting exemplifying embodiments of the invention are described in accompanied dependent claims.

Various non-limiting exemplifying embodiments of the invention both as to constructions and to methods of operation, together with additional objects and advantages thereof, will be best understood from the following description of specific exemplifying embodiments when read in connection with the accompanying drawings.

The verbs “to comprise” and “to include” are used in this document as open limitations that neither exclude nor require the existence of unrecited features. The features recited in depending claims are mutually freely combinable unless otherwise explicitly stated.

### BRIEF DESCRIPTION OF THE FIGURES

The exemplifying embodiments of the invention and their advantages are explained in greater detail below in the sense of examples and with reference to the accompanying drawings, in which:

FIGS. 1a and 1b illustrate a device according to an exemplifying embodiment of the invention,

FIG. 1c shows a view of a section taken along the line A-A shown in FIG. 1a,

FIG. 2 illustrates a device according to an exemplifying embodiment of the invention,

FIG. 3 illustrates a device according to an exemplifying embodiment of the invention,

FIGS. 4a and 4b illustrate a part of equipment according to an exemplifying embodiment of the invention, and

FIGS. 5a and 5b illustrate devices according to exemplifying embodiments of the invention.

### DESCRIPTION OF THE EXEMPLIFYING EMBODIMENTS

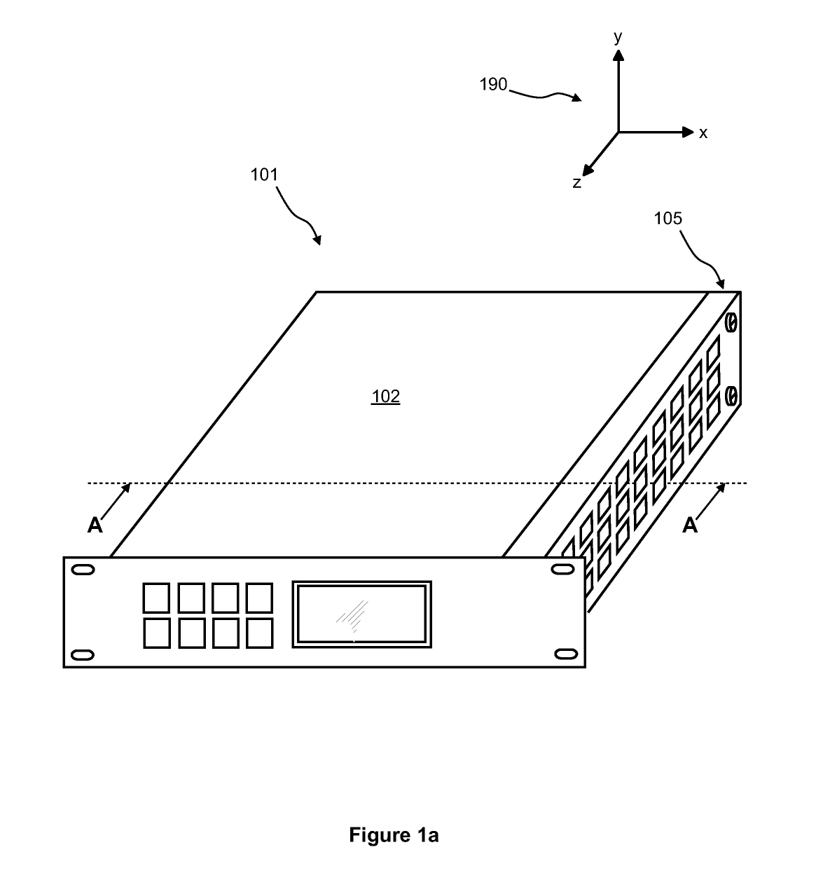

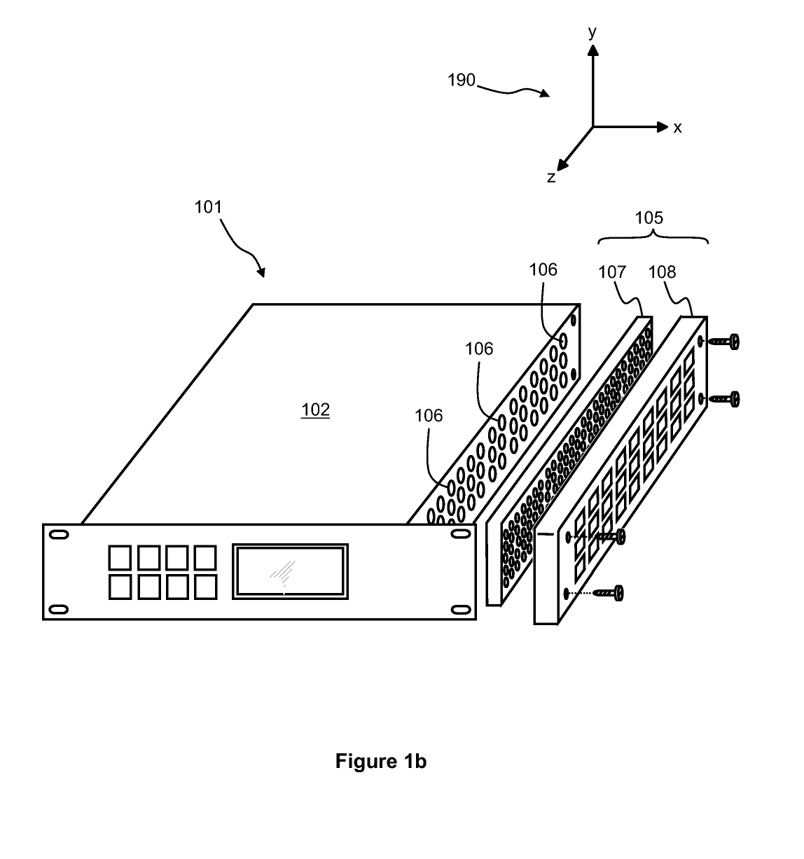

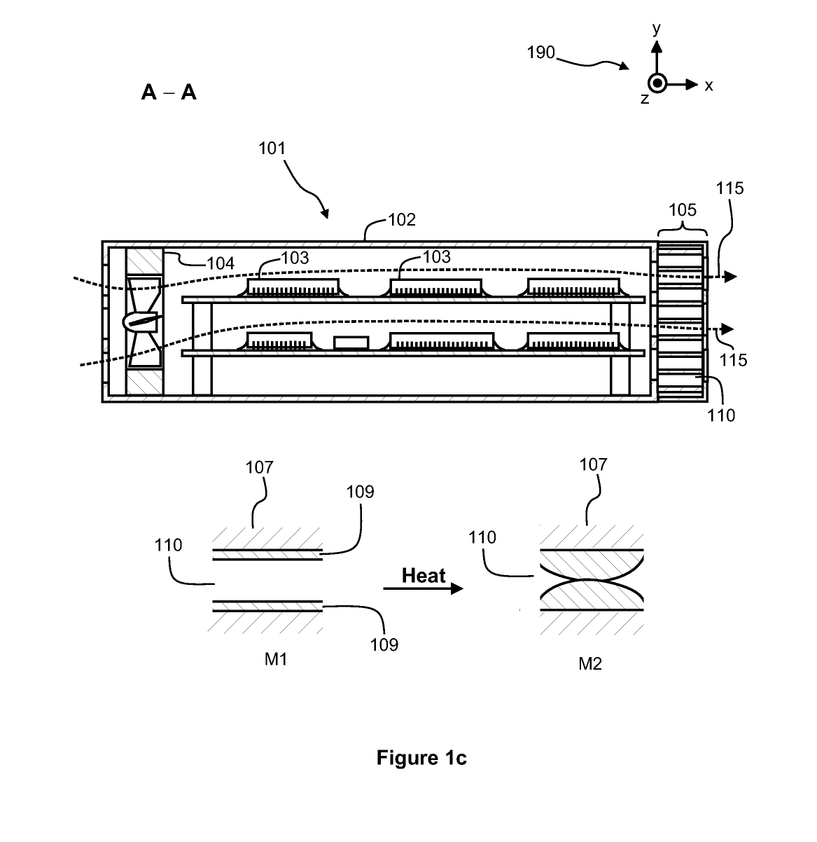

FIG. 1a shows a perspective view of a device 101 according to an exemplifying embodiment of the invention and FIG. 1c shows a view of a section taken along the line A-A shown in FIG. 1a. The device can be, for example but not necessarily, a telecommunication device such as an internet protocol “IP” router, an Ethernet switch, and Asynchronous Transfer Mode “ATM” switch, and/or a multi-protocol label switching “MPLS” switch. The device comprises a casing 102 and a fire protection element 105. FIG. 1b shows the device in a situation in which the fire protection 105 has been detached from the rest of the device. The casing 102 comprises a first wall having one or more ventilation apertures 106 as illustrated in FIG. 1b. The device 101 comprises at least one electrical component 103 inside the casing and at least one fan element 104 configured to produce ventilation flow through the one or more ventilation apertures so as to cool the at least one electrical component. The at least one electrical component 103 and the at least one fan element are shown in FIG. 1c. The ventilation flow is illustrated with dashed arrows 115 shown in FIG. 1c. The fire protection element 105 comprises thermally expanding material configured to suppress the ventilation flow via the one or more ventilation apertures in response to a situation in which the thermally expanding material is exposed to heat and gets expanded. The fire protection element 105 is outside the casing 102, the at least one fan element 104 is mechanically supported to the casing, and the fire protection element is removable and re-installable without detaching the mechanical support between the casing and the at least one fan element. Therefore, the fire protection element 105 can be a post-installable element and thus the need to have two types of devices in a product portfolio can be avoided. In the exemplifying case illustrated in FIGS. 1a-1c, the at least one fan element 104 is inside the casing and the fire protection element 105 is outside the casing and attached to the first wall of the casing. The expression “at least one fan element” means that there can be one or more fan elements successively in the z-direction of the coordinate system 190.

In the exemplifying case illustrated in FIGS. 1a-1c, the fire protection element 105 comprises a grid 107 coated with thermally expanding material 109. The grid 107 is illustrated in FIGS. 1b and 1c, and the thermally expanding material 109 is illustrated in FIG. 1c which shows partial magnifications M1 and M2 of an aperture 110 of the grid 107. The aperture 110 is coated with the thermally expanding material 109 as illustrated in the partial magnification M1. The partial magnification M2 illustrates a situation in which the thermally expanding material has been heated and, as a corollary, has expanded and closed the aperture 110. The thermally expanding material 109 can be, for example, high-temperature foamable paint. The high-temperature foamable paint can be, for example, paint manufactured by Flame Control Corporation and sold as “Flame Control” in the market. The paint contains foamable substance, and, when the foam is produced, the foam is resistive against the fire. It is also possible that the whole grid 107 is made of the thermally expanding material. In the exemplifying case illustrated in FIGS. 1a-1c, the fire protection element 105 further comprises a frame 108 for supporting the grid and having through holes for fastening screws. It is also possible that the grid 107 comprises an adhesive layer for attaching to areas of the first wall surrounding the ventilation apertures 106.

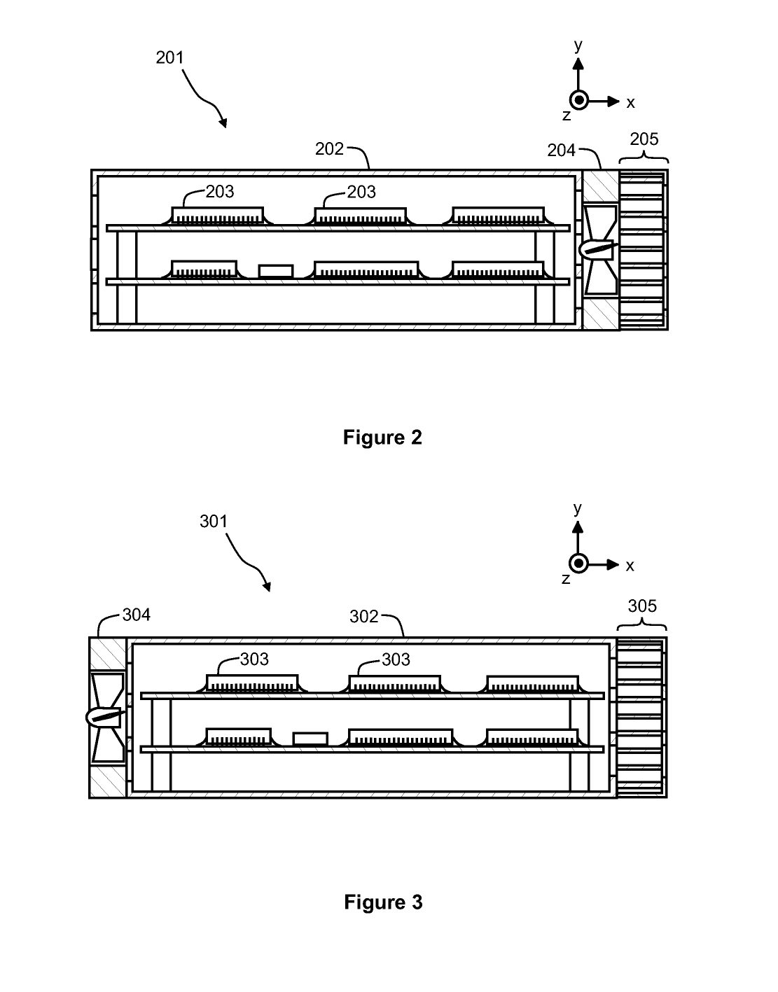

FIG. 2 illustrates a device 201 according to an exemplifying embodiment of the invention. FIG. 2 shows a section view corresponding to that shown in FIG. 1c. The device comprises a casing 202 comprising a first wall having one or more ventilation apertures. The device comprises at least one electrical component 203 inside the casing and at least one fan element 204 configured to produce ventilation flow through the one or more ventilation apertures so as to cool the at least one electrical component. The device comprises a fire protection element 205 that comprises thermally expanding material configured to suppress the ventilation flow via the one or more ventilation apertures in response to a situation in which the thermally expanding material is exposed to heat and gets expanded. The fire protection element 205 is outside the casing 202, the at least one fan element 204 is mechanically supported to the casing, and the fire protection element is removable and re-installable without detaching the mechanical support between the casing and the at least one fan element. In this exemplifying case, the at least one fan element 204 is outside the casing 202 and attached to the first wall of the casing. The fire protection element 205 is attached to the at least one fan element so that the at least one fan element is between the first wall of the casing and the fire protection element as illustrated in FIG. 2.

FIG. 3 illustrates a device 301 according to an exemplifying embodiment of the invention. FIG. 3 shows a section view corresponding to that shown in FIG. 1c. The device comprises a casing 302 comprising a first wall having one or more ventilation apertures. The device comprises at least one electrical component 303 inside the casing and at least one fan element 304 configured to produce ventilation flow through the one or more ventilation apertures so as to cool the at least one electrical component. The device comprises a fire protection element 305 that comprises thermally expanding material configured to suppress the ventilation flow via the one or more ventilation apertures in response to a situation in which the thermally expanding material is exposed to heat and gets expanded. The fire protection element 305 is outside the casing 302, the at least one fan element 304 is mechanically supported to the casing, and the fire protection element is removable and re-installable without detaching the mechanical support between the casing and the at least one fan element. In this exemplifying case, the at least one fan element 304 is outside the casing and attached to a second wall of the casing. The fire protection element 305 is outside the casing and attached to the first wall of the casing. Also the second wall of the casing is provided with ventilation apertures.

In the exemplifying cases shown in FIGS. 1a-1c, 2, and 3, the casing has ventilation apertures on two walls. It is, however, also possible that only one of the walls of the casing is provided with ventilation apertures so that some of the ventilation apertures are arranged to act as inlet apertures and the rest of the ventilation apertures are arranged to act as outlet apertures, and the ventilation fluid, e.g. air, is arranged to flow along a U-shaped path inside the casing.

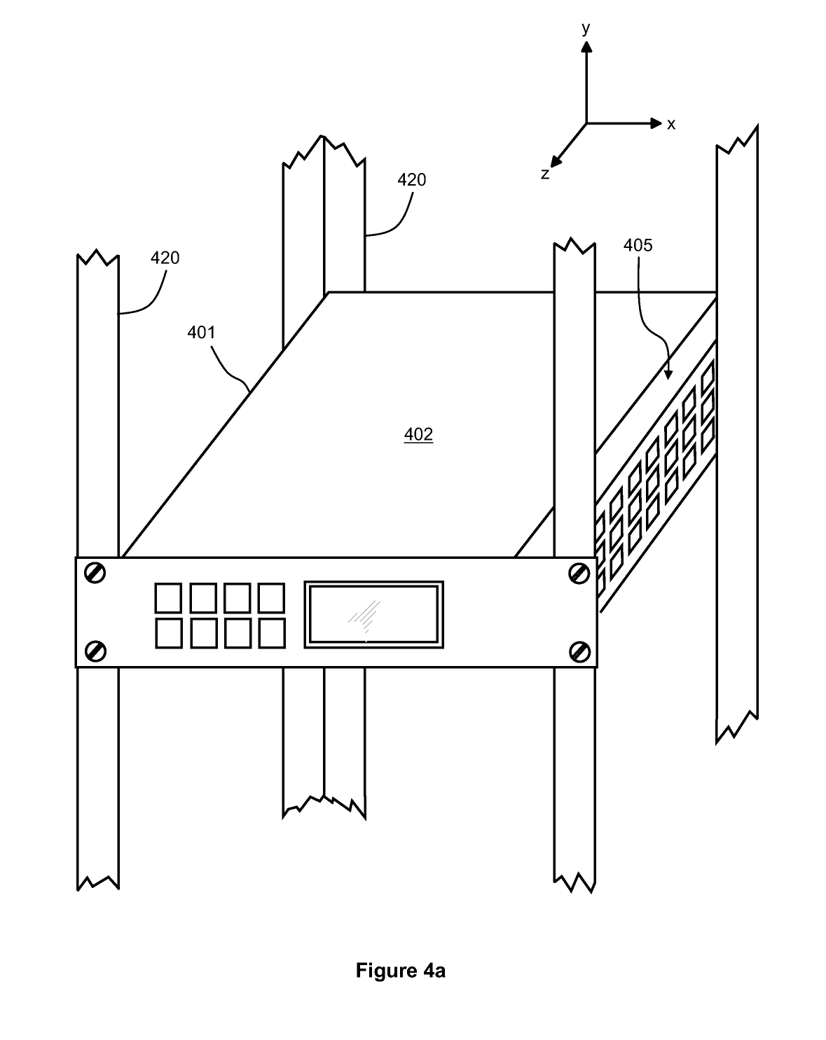

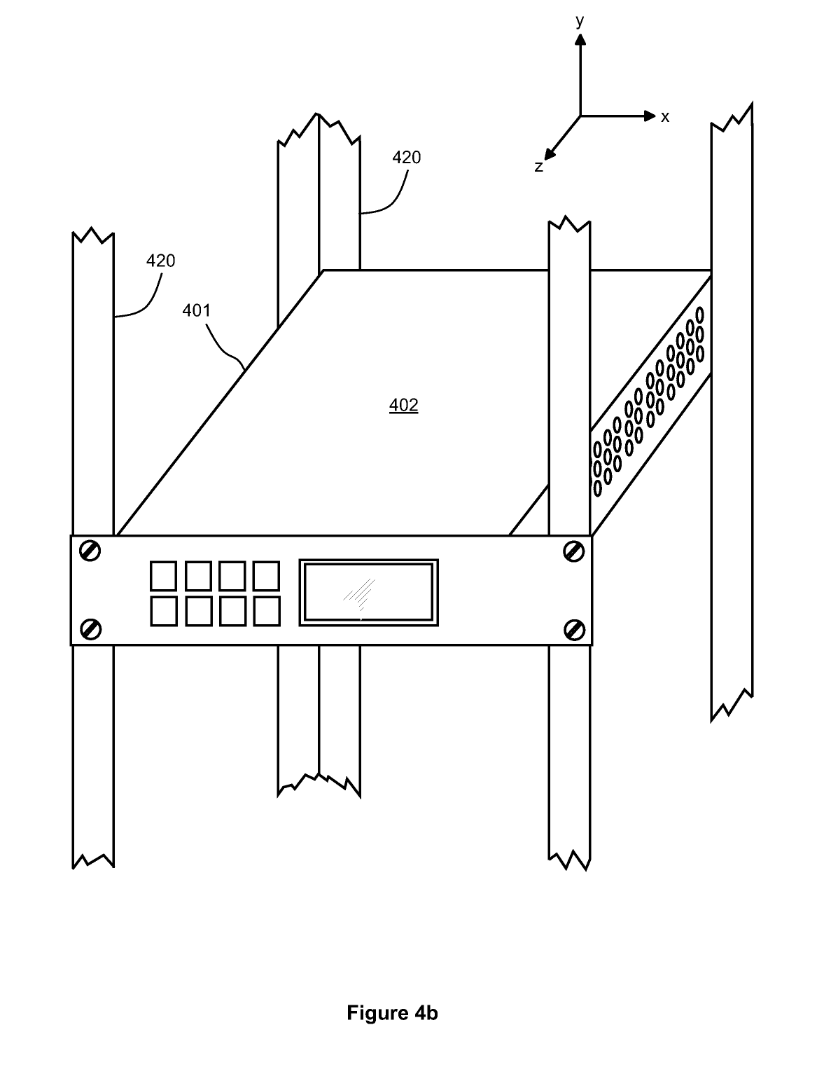

FIGS. 4a and 4b illustrate a part of equipment according to an exemplifying embodiment of the invention. The equipment comprises at least one component device 401 that comprises a casing 402, one or more electrical components inside the casing, and at least one fan element. The casing comprises a wall having ventilation apertures and the at least one fan element is configured to produce ventilation flow through the ventilation apertures so as to cool the one or more electrical components. The component device further comprises a fire protection element 405 comprising thermally expanding material configured to suppress the ventilation flow via the ventilation apertures in response to a situation in which the thermally expanding material is exposed to heat and gets expanded. The fire protection element is outside the casing, the at least one fan element is mechanically supported to the casing, and the fire protection element is removable and re-installable without detaching the mechanical support between the casing and the at least one fan element. Therefore, the fire protection element 405 can be a post-installable element. The equipment further comprises a body device 420 comprising mechanical structures for receiving the component device 401 so that the component device 401 is in its operating position when supported by the mechanical structures. The mechanical structures of the body-device are suitable for supporting the component device 401 in its operating position also when the component device is without the fire protection element 405. FIG. 4a illustrates the equipment when the component device 401 is provided with the fire protection element 405, and FIG. 4b illustrates the equipment when the component device 401 is without the fire protection element.

The equipment can be, for example but not necessarily, telecommunication equipment where the body device 420 is a rack for supporting the component device 401 and the component device comprises a processing system for supporting at least one on the following data transfer protocols: Internet Protocol “IP”, Ethernet protocol, MultiProtocol Label Switching “MPLS” protocol, Asynchronous Transfer Mode “ATM”.

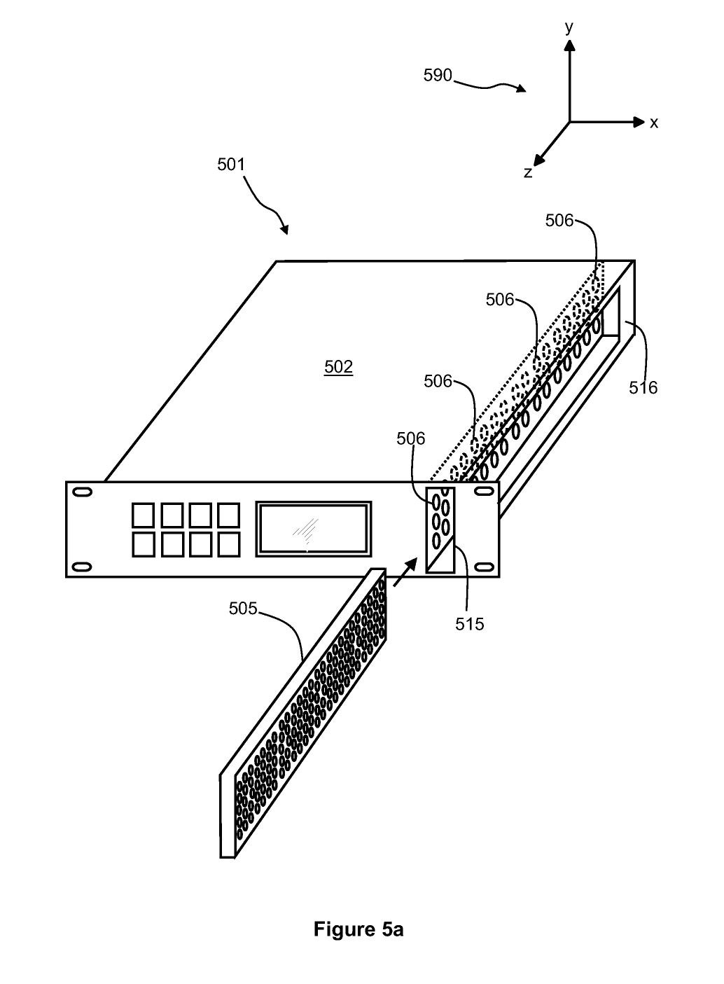

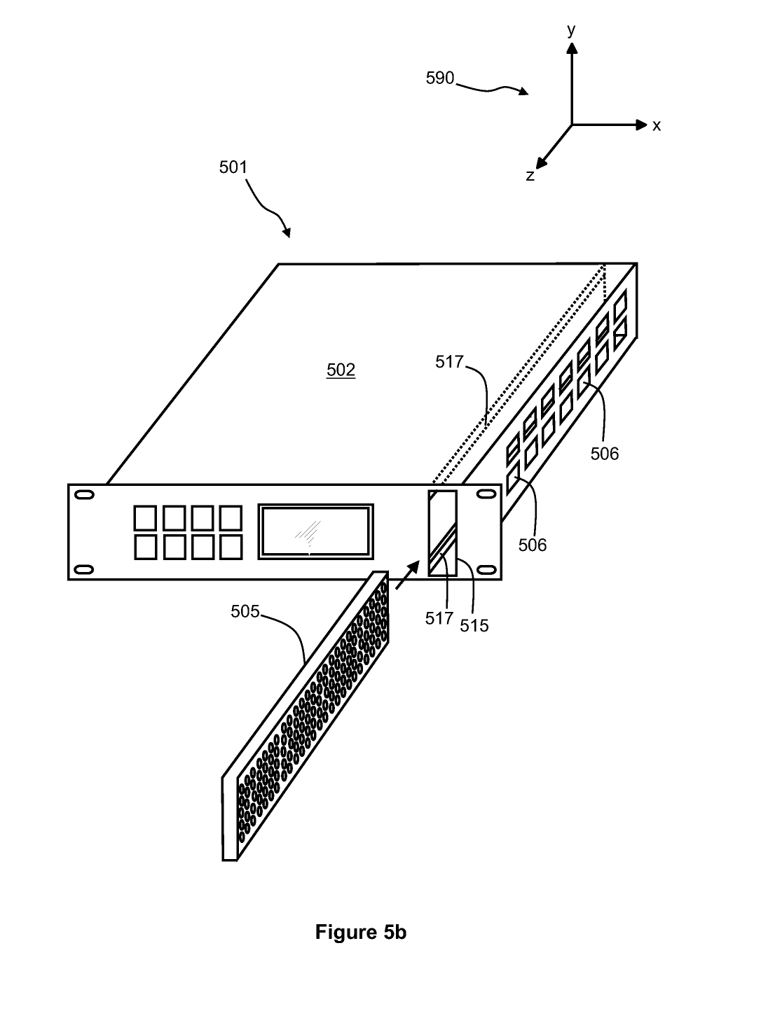

FIGS. 5a and 5b show perspective views of devices 501 according to exemplifying embodiments of the invention. Each of the devices comprises a casing 502 comprising a first wall having one or more ventilation apertures 506. Each of the devices comprises at least one electrical component inside the casing and at least one fan element configured to produce ventilation flow through the one or more ventilation apertures so as to cool the at least one electrical component. Each of the devices comprises a fire protection element 505 that comprises thermally expanding material configured to suppress the ventilation flow via the one or more ventilation apertures in response to a situation in which the thermally expanding material is exposed to heat and gets expanded. The at least one electrical component and the at least one fan element are not shown in FIGS. 5a and 5b. The at least one fan element is mechanically supported to the casing, and the fire protection element 505 is removable and re-installable without detaching the mechanical support between the casing and the at least one fan element. The casing 502 comprises an aperture 515 enabling the fire protection element 505 to be pushed in the negative z-direction of the coordinate system 590 into the casing 502.

In the exemplifying case illustrated in FIG. 5a, the first wall comprising the ventilation apertures 506 is inside the casing and therefore some of the ventilation apertures are presented with dashed lines in FIG. 5a. An outer wall 516 of the casing is provided with only one ventilation aperture so that the outer wall 516 actually constitutes guide tracks for supporting the fire protection element 505 in the x-direction. It is also possible that the outer wall 516 is provided with a plurality of ventilation apertures.

In the exemplifying case illustrated in FIG. 5b, the first wall comprising the ventilation apertures 506 is an outer wall the casing. The casing comprises guide tracks 517 for supporting the fire protection element 505 in the x-direction. It is also possible that, instead of the guide tracks 517, the casing includes a wall provided with a plurality of ventilation apertures. It is also possible that the first wall has only one ventilation aperture so that the first wall actually constitutes guide tracks for supporting the fire protection element 505 in the x-direction. If there are mere guide tracks on both sides of the fire protection element 505, there can be a need to use a separate protector grid on the place of the fire protection element 505 when the fire protection element is not used because otherwise the internal components of the device could not be sufficiently protected against external objects.

The specific examples provided in the description given above should not be construed as limiting the applicability and/or the interpretation of the appended claims. For example, a wall comprising one or more ventilation apertures can be constructed in various ways, e.g. by providing a sheet of metal or other suitable material with one or more through holes or by making a grid of wires or strips.

What is claimed is:

1. A device comprising the following parts:
a casing comprising a first wall having one or more ventilation apertures,
at least one electrical component inside the casing,
at least one fan element configured to produce ventilation flow through the one or more ventilation apertures so as to cool the at least one electrical component, and
a fire protection element comprising thermally expanding material configured to suppress the ventilation flow via the one or more ventilation apertures in response to a situation in which the thermally expanding material is exposed to heat and gets expanded,
wherein the at least one fan element is mechanically supported to the casing and the fire protection element is removable and re-installable without detaching the mechanical support between the casing and the at least one fan element.

2. A device according to claim 1, wherein the at least one fan element is inside the casing and the fire protection element is outside the casing and attached to the first wall of the casing.

3. A device according to claim 1, wherein the at least one fan element is outside the casing, the at least one fan element is attached to the first wall of the casing, and the fire protection element is attached to the at least one fan element so that the at least one fan element is between the first wall of the casing and the fire protection element.

4. A device according to claim 1, wherein the at least one fan element is outside the casing, the at least one fan element is attached to a second wall of the casing, and the fire protection element is outside the casing and attached to the first wall of the casing, the second wall of the casing having one or more ventilation apertures.

5. A device according to claim 1, wherein the casing comprises an aperture enabling the fire protection element to be pushed into the casing.

6. A device according to claim 1, wherein the fire protection element comprises a grid coated with the thermally expanding material.

7. A device according to claim 2, wherein the fire protection element comprises a grid coated with the thermally expanding material.

8. A device according to claim 3, wherein the fire protection element comprises a grid coated with the thermally expanding material.

9. A device according to claim 4, wherein the fire protection element comprises a grid coated with the thermally expanding material.

10. A device according to claim 5, wherein the fire protection element comprises a grid coated with the thermally expanding material.

11. A device according to claim 1, wherein the fire protection element comprises a grid made of the thermally expanding material.

12. A device according to claim 2, wherein the fire protection element comprises a grid made of the thermally expanding material.

13. A device according to claim 3, wherein the fire protection element comprises a grid made of the thermally expanding material.

14. A device according to claim 4, wherein the fire protection element comprises a grid made of the thermally expanding material.

15. A device according to claim 5, wherein the fire protection element comprises a grid made of the thermally expanding material.

16. A device according to claim 6, wherein the fire protection element further comprises a frame for supporting the grid.

17. A device according to claim 11, wherein the fire protection element further comprises a frame for supporting the grid.

18. A device according to claim 6, wherein the grid comprises an adhesive layer for attaching to areas of the first wall surrounding the ventilation apertures.

19. A device according to claim 11, wherein the grid comprises an adhesive layer for attaching to areas of the first wall surrounding the ventilation apertures.

20. A device according to claim 1, wherein the at least one electrical component constitutes a processing system for supporting at least one on the following data transfer protocols: Internet Protocol “IP”, Ethernet protocol, MultiProtocol Label Switching “MPLS” protocol, Asynchronous Transfer Mode “ATM”.

21. Equipment comprising:
at least one component device, and
a body device comprising mechanical structures for receiving the component device so that the component device is in its operating position when supported by the mechanical structures,
the at least one component device comprising the following parts:
a casing comprising a first wall having one or more ventilation apertures,
at least one electrical component inside the casing,
at least one fan element configured to produce ventilation flow through the one or more ventilation apertures so as to cool the at least one electrical component, and
a fire protection element comprising thermally expanding material configured to suppress the ventilation flow via the one or more ventilation apertures in response to a situation in which the thermally expanding material is exposed to heat and gets expanded,
wherein the at least one fan element is mechanically supported to the casing and the fire protection element is removable and re-installable without detaching the mechanical support between the casing and the at least one fan element, and wherein the mechanical structures of the body-device are suitable for supporting the component device in its operating position also when the component device is without the fire protection element.

22. Equipment according to claim 21, wherein the equipment is telecommunication equipment where the body device is a rack for supporting the component device and the component device comprises a processing system for supporting at least one on the following data transfer protocols: Internet Protocol “IP”, Ethernet protocol, Multi Protocol Label Switching “MPLS” protocol, Asynchronous Transfer Mode “ATM”.
